(19) United States
(12) Patent Application Publication
(10) Pub. No.: US 2009/0093113 A1
(43) Pub. Date: Apr. 9, 2009

(54) Electrochemical etching of through silicon vias

(76) Inventor: John Flake, (US)

Correspondence Address: Jason P. Mueller;Adams and Reese, LLP, 4400 One Houston Center, 1221 McKinney Street, Houston, TX, 77010, US

(21) Appl. No.: 12/286,003

(22) Filed: Sep. 26, 2008

Related U.S. Application Data
(60) Provisional application No. 60/977,208, filed on Oct. 3, 2007.

(51) Int. Cl. H01L 21/4763; H01L 21/311

(52) U.S. Cl. 438/618; 438/694; 257/E21.575; 257/E21.219

(57) ABSTRACT

A process is disclosed to form through silicon vias in a silicon wafer. The method comprises, forming a dielectric layer on a silicon wafer, forming a masking layer using photolithography, etching the dielectric layer, and electrochemically etching a through silicon via in the silicon wafer.

### CROSS-REFERENCE TO RELATED APPLICATIONS

This application claims priority to non-provisional application No. 60/977,208 filed Oct. 3, 2007 entitled “Methods for Fabrication of Nano-Devices”.

### STATEMENT REGARDING FEDERALLY SPONSORED RESEARCH OR DEVELOPMENT

Not applicable.

### THE NAMES OF THE PARTIES TO A JOINT RESEARCH AGREEMENT

Not applicable.

### INCORPORATION-BY-REFERENCE OF MATERIAL SUBMITTED ON COMPACT DISC

Not applicable.

### BACKGROUND OF THE INVENTION

1. Field of the Invention

The present invention relates to the formation of through silicon vias in a silicon wafer. More particularly, this invention relates to a method for forming such a through silicon vias.

2. Description of Related Art

Most electronic devices (cell phones, computers) are made using a plurality of packaged die on printed circuit board(s). To improve the performance of electronic devices and reduce their overall size, some die may be located nearby each other or even within the same package. More recently, there has been considerable interest in stacking multiple die within the same package. This stacking allows several die to be intimately connected using three-dimensional (3D) interconnects and solder joints. One method of connecting individual die is to use interconnects that cross through the wafer from the front to the backside of the die. These through-silicon 3D interconnects allow front to back stacking of multiple die. In one example, 10 DRAM memory die may be stacked to form a dense DRAM module. In another example, a CMOS image sensor may be stacked onto a microprocessor. In both cases, the overall power consumption is lowered, the signal transmission speed is improved, and the device has a smaller size compared to cases where each die requires a separate package.

In conventional processes, through silicon vias (or TSVs) are made by laser ablation or vacuum etching processes such as: reactive ion etching, deep reactive ion etching, plasma etching, or ion beam milling. Although these methods are capable of creating TSVs, there are several deficiencies including slow etch rates, high surface roughness, low anisotropy, and defectivity. In accordance with the invention, these deficiencies are addressed in a through silicon via processing method.

Illustrative patents disclosing a “through silicon via” are shown in U.S. Pat. No. 7,425,499 entitled “Methods for Forming Interconnects in Vias and Microelectronic Workpieces Including Such Interconnects”, U.S. Pat. No. 7,413,979 entitled “Methods for Forming Vias in Microelectronic Devices, and Methods for Packaging Microelectronic Devices”, U.S. Pat. No. 7,410,884 entitled “3D Integrated Circuits Using thick Metal for Backside Connections and Offset Bumps”, U.S. Pat. No. 7,317,256 entitled “Electronic Packaging Including Die with Through Silicon Via”, U.S. Pat. No. 7,241,675 entitled “Attachment of Integrated Circuit Structures and Other Substrates to Substrates with Vias”, U.S. Pat. No. 7,241,641 entitled “Attachment of Integrated Circuit Structures and Other Substrates to Substrates with Vias”, U.S. Pat. No. 7,111,149 entitled “Method and Apparatus for Generating a Device ID for Stacked Devices”, U.S. Pat. No. 7,081,408 entitled “Method of Creating a Tapered Via Using a Receding Mask and Resulting Structure”, U.S. Pat. No. 6,924,551 entitled “Through Silicon Via, Folded Flex Microelectronic Package”, U.S. Pat. No. 6,495,879 entitled “Ferroelectric Memory Device Having a Protective Layer” and U.S. Pat. No. 6,255,204 entitled “Method for Forming a Semiconductor Device”.

For example, U.S. Pat. No. 7,413,979 as prior art stipulates “etching a hole” but doesn't say how the hole (via) is created and it stipulated that a passage (via) is created through the die.

### BRIEF SUMMARY OF THE INVENTION

The present invention is for a method for forming through silicon vias, including deep vias, where a dielectric layer is deposited on the surface of the silicon wafer.

In accordance with the invention, a new process for fabricating through silicon vias is provided. The process employs a silicon wafer, dielectric deposition, photolithography, dielectric etching and etching of the silicon using an electrochemical process.

Stacking several semiconductor die in a single package using three dimensional (3D) interconnects provides a method to increase the density and performance of microelectronic devices. For example, several flash memory die may be stacked to increase the memory available in a single package. In another example, several Dynamic Random Access Memory die is typically less than 200 μm and interconnects between the die are typically <50 μm, the thickness of several stacked die together is typically less than 5 mm. In addition to improved packing density, there are other advantages to stacking die, including: lower power consumption, increased bandwidths, and greater performance.

In order to stack multiple die in a 3D assembly, electrical connections are needed to transfer electrical signals vertically from one die to another. These vertical connections through the chip are commonly referred to as 3D interconnects. Three-dimensional interconnects allow the interconnection of multiple die (or chips) using vertical interconnects through the die and bond pads spanning from the top surface of one die to the bottom surface of another die. Vertical interconnects through the die are usually created using a process including the formation of through silicon vias or TSVs and the metallization of TSVs.

### BRIEF DESCRIPTION OF THE DRAWINGS

For a further understanding of the nature, objects, and advantages of the present invention, reference should be had to the following detailed description, read in conjunction with the following drawings, wherein like reference numerals denote like elements and wherein:

FIG. 1 shows a portion of a silicon wafer with a dielectric layer deposited on the surface of the wafer;

FIG. 2 shows a portion of the wafer of FIG. 1 after photolithography and etching of the dielectric layer;

FIG. 3 shows a portion of the wafer of FIG. 1 after a first etch; and

FIG. 4 shows a portion of the wafer of FIG. 1 after electrochemical etching of through silicon vias which may occur without the step of FIG. 3 but the step of FIG. 3 being included is preferred.

### DESCRIPTION OF THE PREFERRED EMBODIMENT

The present invention includes dielectric deposition, photolithography, dielectric etching, and etching of the silicon using an electrochemical process.

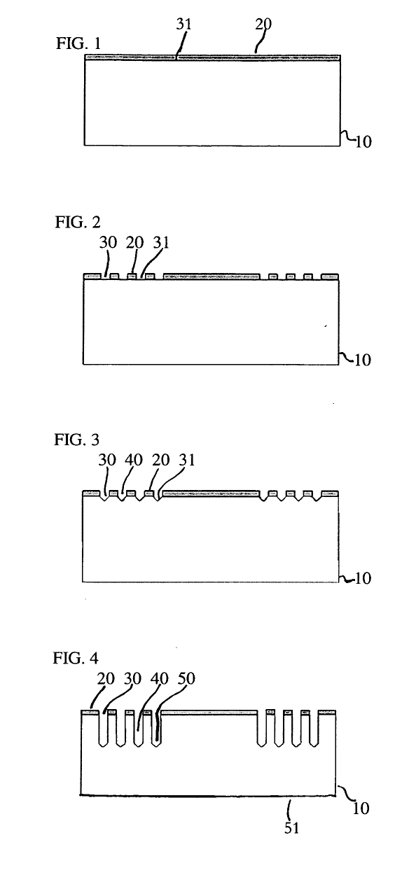

FIG. 1 illustrates a portion of a silicon wafer 10, which has a dielectric 20 deposited on the surface 31 of the wafer 10. This is a work piece for the invention. In the figures that follow FIG. 1, FIGS. 2-4, procedures are practiced on wafer 10. These procedures essentially involve electrochemical etch operations for etching through silicon via, such as through silicon via 50 in FIG. 4. Ultimately, the through silicon via 50 may go all the way through wafer 10 or surface 51 of the wafer 10 may be background (not shown) until the through silicon via 50 extends through the wafer 10 and with the end of the through silicon via 50 opening to the ground surface 51.

In this regard, FIG. 2, shows a portion of the wafer 10 with a dielectric layer 20 after the steps of photolithography and etching of the dielectric layer 20. Thus, FIG. 2 shows a portion of wafer 10 having the dielectric layer 20 to form openings 30 to the silicon 31 from the dielectric layer 20 which may be of varying topography. After the etch of dielectric layer 20 is used to form the opening 30 to this silicon 31, leaving the silicon 31 at the bottom of the channels or openings 30, such as channel 31 disclosed in the next step.

As the preferred embodiment, FIG. 3 shows the exposure of the silicon 31 of the wafer 10 in the first etch as an option instead of following the process of FIG. 2 followed by the process of FIG. 4. Practicing this as the invention in FIG. 3 is the preferred embodiment. Such process goes directly to FIG. 4, if preferable manner of FIG. 4 is to process from FIG. 1 to FIG. 2, and then FIG. 2 to FIG. 4. Thus, FIG. 2 shows a portion of the wafer 10 with the photolithography and etching of dielectric layer 20 to form the openings 30, the base of which openings 30 as shown in FIG. 2 are the silicon 31 of the silicon wafer 10. FIG. 3 shows the portion of the wafer 10 after a first etch 40. If FIG. 4 rather than FIG. 3 is the next step to chemically form the finished through silicon via 50, it is the alternate embodiment. Alternatively, for the preferred embodiment, the step of FIG. 2 is followed by the step of FIG. 3. FIG. 3 shows the openings 30 penetrating the wafer 10 silicon 31 and exposing beyond the silicon 31 by etch 40 exposing the openings 30 into the silicon 31.

The invention claimed is:

1. A method for forming a through silicon via in a silicon wafer, comprising:
depositing a dielectric layer on the silicon wafer;
forming a masking layer on the silicon wafer using photolithography;
forming the dielectric layer with open regions to form a pattern on the silicon wafer;
selectively etching through the dielectric layer in the open regions of the pattern in a first etch; and
selectively etching a through silicon via in a second etch using an electrochemical process.

2. The method in claim 1 where multiple silicon vias are formed simultaneously.

3. The method in claim 1 where the silicon wafer is thinned to less than 500 micrometers prior to electrochemical etching.

4. The method in claim 1 where the dielectric includes silicon nitride or silicon dioxide.

5. The method in claim 1 where the electrochemical etch is preceded by a chemical etch.

6. The method in claim 1 where there is a electrochemical cell and the wafer is made the anode in an electrochemical cell.

7. The method in claim 6 where the electrochemical cell contains a fluoride source.

8. The method in claim 1 where the silicon wafer include a silicon-on-insulator wafer.

9. A method for forming a through silicon via in a silicon wafer having a silicon surface, comprising:
forming transistors on the silicon wafer;
forming interconnects above the silicon surface;
depositing a dielectric layer with open regions to form a pattern on the silicon wafer;
forming a masking layer on the silicon wafer using photolithography;
selectively etching through the dielectric layer in the open regions of the pattern; and
selectively etching a through silicon via using an electrochemical process.

10. The method in claim 9 where multiple silicon vias are formed simultaneously.

11. The method in claim 9 where the silicon wafer is thinned to less than 500 micrometers prior to electrochemical etching.

12. The method in claim 9 where the dielectric includes silicon nitride.

13. The method in claim 9 where the dielectric includes silicon dioxide.

14. The method in claim 9 where the electrochemical etch is preceded by a chemical etch.

15. The method in claim 9 where the silicon wafer is made the anode in an electrochemical cell.

16. The method in claim 14 where the electrochemical cell contains a fluoride source.

17. The method in claim 9 where the silicon wafers include a silicon-on-insulator wafer.
